(19) United States
(12) Patent Application Publication
(10) Pub. No.: US 2012/0103662 A1
(43) Pub. Date: May 3, 2012

(54) Printed circuit board and manufacturing method thereof

(75) Inventors: Chang Bo Lee, Gyeonggi-do (KR); Cheol Ho Choi, Gyeonggi-do (KR); Yoong Oh, Gyeonggi-do (KR)

(73) Assignee: SAMSUNG ELECTRO-MECHANICS CO., LTD., Suwon (KR)

(21) Appl. No.: 13/064,331

(22) Filed: Mar. 18, 2011

(30) Foreign Application Priority Data
Nov. 2, 2010 (KR) 10-2010-0108179

(51) Int. Cl. H05K 1/02; B05D 5/00; H05K 3/10; H05K 3/22

(52) U.S. Cl. 174/250; 156/60; 427/97.6; 29/846

(57) ABSTRACT

Disclosed herein are a printed circuit board including a first low-viscosity solder resist layer formed on one surface of a substrate having circuit patterns formed thereon and a second high-viscosity solder resist layer stacked on the first solder resist layer, thereby being advantageous in controlling the deviation in application thickness of solder resist (SR), while having excellent adhesion to the substrate, and a manufacturing method thereof.

### CROSS REFERENCE(S) TO RELATED APPLICATIONS

This application claims the benefit under 35 U.S.C. Section 119 of Korean Patent Application Serial No. 10-2010-0108179, entitled “Printed Circuit Board and Manufacturing Method Thereof” filed on Nov. 2, 2010, which is hereby incorporated by reference in its entirety into this application.

### BACKGROUND OF THE INVENTION

1. Technical Field

The present invention relates to a printed circuit board and a manufacturing method thereof, and more particularly, to a printed circuit board including a first low-viscosity solder resist layer formed on one surface of a substrate having circuit patterns formed thereon and a second high-viscosity solder resist layer stacked on the first solder resist layer, thereby being advantageous in controlling the deviation in application thickness of solder resist (SR), while having excellent adhesion to the substrate, and a manufacturing method thereof.

2. Description of the Related Art

When manufacturing a printed circuit board (PCB), a solder resist (SR) is applied as an outermost layer. The solder resist, which is one of the insulating permanent coating materials, is a coating covering a wiring circuit to prevent unintended connection from occurring by soldering performed at the time of mounting components. Since the solder resist coats the wiring and shields portions other than lands required for soldering the components, that is, the perimeter of the portions on which the components are mounted, it is referred to as a solder mask. The solder resist prevents short-circuit, corrosion, contamination, and the like, of the PCB circuit and remains as a coating on a substrate even after the substrate is manufactured to protect the PCB circuit from external shock, moisture, and chemical material.

The kind of SR is mainly divided into a liquid type and a film type. Recently, technologies have progressed toward the film type rather than the liquid type. This is the reason that the film type is advantageous in controlling the deviation in application thickness and is excellent in terms of storage and utilization. However, as the thickness of the SR becomes thinner (30 μm or less), the film type has lower adhesion as compared to the liquid type. This is the reason that the film type has relatively low fluidity (relatively high viscosity), such that when uniform pressure is not transferred over the entire area during coating, bonding is not locally performed satisfactorily. Conversely, the liquid type (SR) is relatively advantageous in terms of adhesion even though the thickness of the SR becomes thinner.

In the related art, a dry film SR (high viscosity SR) has been generally applied to a base substrate using a vacuum laminator once, which is advantageous in controlling the deviation in the application thickness, an advantage of the film type; however, disadvantageous in terms of adhesion.

In addition, elements may be mounted by an underfill process. When a solder resist layer is not flat, a shape of a fillet formed through the underfill process is not maintained to be uniform, thereby deteriorating reliability of a product.

A coating process of a solder resist according to the related art is performed in the order of a solder resist pretreatment process, a primary coating by roller or screen printing and temporal hardening process, a secondary coating and temporal hardening process, an exposure process, a development process, and a UV firing process.

In the case of the related art as described above, the solder resist layer is influenced by a form of a circuit pattern, such that a surface of the solder resist layer may become non-flat, which is mainly generated in the case of using the liquid-type solder resist. When the solder resist layer is formed to be non-flat, it causes a non-uniform fillet during the underfilling of an assembly process. That is, in a manufacturing process of the printed circuit board, flatness of the solder resist layer is one of the important factors for securing reliability of the product.

### SUMMARY OF THE INVENTION

An object of the present invention is to provide a printed circuit board including a first low-viscosity solder resist layer formed on one surface of a substrate having circuit patterns formed thereon and a second high-viscosity solder resist layer stacked on the first solder resist layer, thereby being advantageous in controlling the deviation in application thickness of solder resist (SR), while having excellent adhesion, and a manufacturing method thereof.

According to an exemplary embodiment of the present invention, there is provided a printed circuit board, including: a first low-viscosity solder resist layer formed on one surface of a substrate having circuit patterns formed thereon; and a second high-viscosity solder resist layer stacked on the first solder resist layer.

According to another exemplary embodiment of the present invention, there is provided a printed circuit board, including: a first liquid-type solder resist layer formed on one surface of a substrate having circuit patterns formed thereon; and a second solid-type solder resist layer stacked on the first solder resist layer.

The first solder resist layer may be formed by coating and hardening a solder resist having the viscosity of 1 P or more to 1,000 P or less, and the second solder resist layer may be formed by stacking a solder resist having the viscosity of 10,000 P or more to 100,000,000 P or less.

The second solder resist layer may be formed by repetitively stacking at least one solder resist layer.

According to another exemplary embodiment of the present invention, there is provided a manufacturing method of a printed circuit board, including: forming a first low-viscosity or liquid-type solder resist layer on one surface of a substrate having circuit patterns formed thereon; temporally heating the first solder resist layer; and stacking a second high-viscosity or solid-type solder resist layer on the first solder resist layer.

The forming the first solder resist layer may be performed by a roll coating process.

The stacking the second solder resist layer may stack a second high-viscosity or solid-type solder resist as at least one layer.

The manufacturing method of a printed circuit board may further include planarizing the first solder resist layer by applying pressure to the second solder resist layer, after the stacking the second solder resist layer.

The manufacturing method of a printed circuit board may further include forming a predetermined solder resist pattern in the first and second solder resist layers, corresponding to the circuit patterns; and hardening the solder resist pattern.

### BRIEF DESCRIPTION OF THE DRAWINGS

FIG. 1 is a flowchart showing a manufacturing method of a printed circuit board according to an exemplary embodiment of the present invention;

FIG. 2 is a process view showing a manufacturing method of a printed circuit board according to an exemplary embodiment of the present invention;

FIG. 3 is a cross-sectional view of a printed circuit board manufactured according to an exemplary embodiment of the present invention and a flip chip bonded to the printed circuit board; and

FIG. 4 is a perspective view of a printed circuit board manufactured according to an exemplary embodiment of the present invention and a flip chip bonded to the printed circuit board.

### DESCRIPTION OF THE PREFERRED EMBODIMENTS

Hereinafter, exemplary embodiments of the present invention will be described in detail with reference to the accompanying drawings. The terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept of the term to describe most appropriately the best method he or she knows for carrying out the invention.

Therefore, the configurations described in the embodiments and drawings of the present invention are merely the most preferable embodiments but do not represent all of the technical spirit of the present invention. Thus, the present invention should be construed as including all the changes, equivalents, and substitutions included in the spirit and scope of the present invention at the time of filing this application.

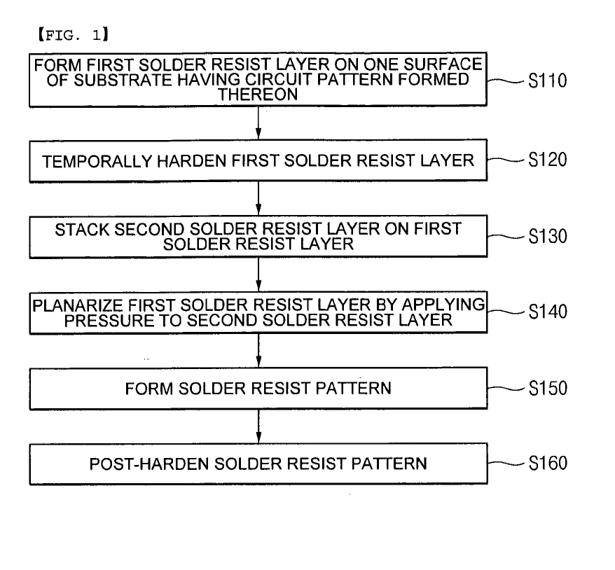

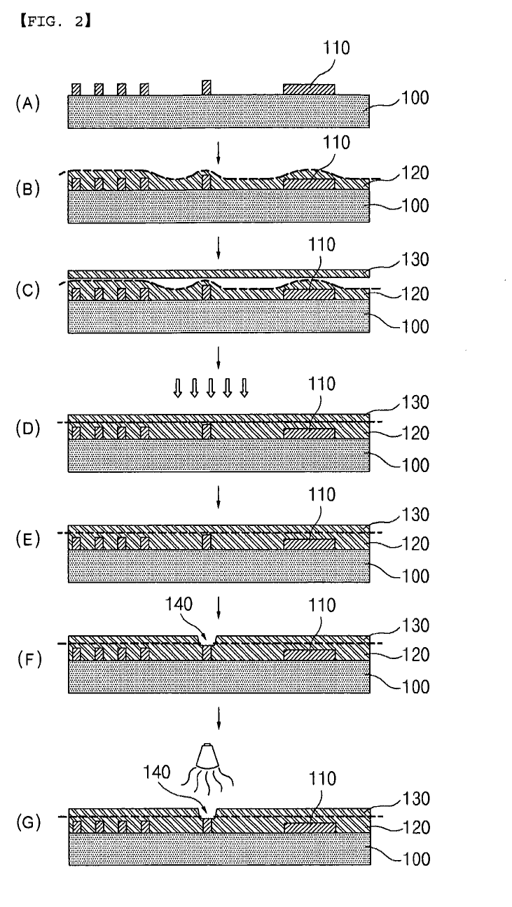

FIG. 1 is a flowchart showing a manufacturing method of a printed circuit board according to an exemplary embodiment of the present invention, and FIG. 2 is a process view showing a manufacturing method of a printed circuit board according to an exemplary embodiment of the present invention.

Referring to FIG. 2, a substrate 100, circuit patterns 110, a first solder resist layer 120, a second solder resist layer 130, and a solder resist pattern 140 are shown.

A printed circuit board according to an exemplary embodiment of the present invention is configured to include a first low-viscosity (liquid-type) solder resist layer formed on one surface of a substrate having circuit patterns formed thereon and a second high-viscosity (solid-type) solder resist layer stacked on the first solder resist layer. That is, the present invention provides a structure of a printed circuit board in which the low-viscosity (liquid-type) solder resist layer and the high-viscosity (solid-type) solder resist layer compensate for the disadvantages of each other, and a manufacturing method thereof. Accordingly, the present invention configures the printed circuit board to include both of the low-viscosity (liquid-type) solder resist layer having excellent adhesion and the high-viscosity (solid-type) solder resist layer being advantageous in controlling the deviation in application thickness.

Herein, the first solder resist layer is formed by coating and hardening a solder resist having the viscosity of 1 P or more to 1,000 P or less, and the second solder resist layer is formed by stacking a solder resist having the viscosity of 10,000 P or more to 100,000,000 P or less.

The viscosity is indicated by Poise as a CGS unit, and uses P as a symbol. 1 P indicates the state in which 1 g of fluid moves by 1 cm for one second. 1 P is excessively large to indicate the viscosity of the fluid. Therefore, centiPoise (cP), which is 1/100 of P, is generally used. For example, pure viscosity at 20° C. is 1.002 cP.

The substrate having the circuit patterns formed thereon has roughness of 0.1 to 1 μm. In order to introduce the solder resist between the circuit patterns having this roughness (in order to improve adhesion), a liquid-type solder resist is more efficient than a solid-type solder resist. The liquid-type solder resist is very efficient in the case of having the viscosity of 100 P, and preferably may have low viscosity of 1 P or more to 1,000 P or less. In addition, the solid-type solder resist that is advantageous in controlling the deviation in application thickness preferably maintains the solid phase, is generally referred to as a film type, and has viscosity of 10,000 P or more. The solid-type solder resist may preferably have the viscosity of 100,000,000 P or less.

Herein, the solder resist having a defined viscosity should be used. In general, since ink produced from an ink producer has viscosity controlled to some degree, it may be used as the solder resist. Furthermore, in the case in which the viscosity needs to be more finely controlled, the viscosity may be lowered by generating heat during the agitating of the ink to raise the temperature thereof. In addition, in the case of the solid-type film, the viscosity may be lowered by raising the compression temperature during the manufacturing of the film.

Also, in the present invention, the second solder resist layer may be formed by repetitively stacking at least solder resist layers. That is, the high-viscosity (solid-type) solder resist is very advantageous in controlling the deviation in application thickness in view of the characteristics of the material and may be formed by repetitively stacking a plurality of solder resist layers according to the desired thickness of the printed circuit board.

Hereinafter, a manufacturing method of a printed circuit board according to an exemplary embodiment of the present invention will be described.

A step (S110) of forming a first low-viscosity (liquid-type) solder resist layer on one surface of a substrate having circuit patterns formed thereon will be described with reference to FIGS. 2A and 2B. The circuit patterns 110 are formed on one surface of the substrate 100 by an additive process or a subtractive process.

According to the additive process, the circuit patterns 110 are directly formed by a method such as plating, etc. According to the subtractive process, the circuit patterns 110 are formed by forming a layer made of a conductive material on a substrate using a copper foil, etc., and etching portions not corresponding to the circuit pattern 110.

A pre-treatment process may be additionally performed before forming the first solder resist layer 120 covering the circuit pattern 110. In the pre-treatment process, the circuit patterns are chemically etched to increase adhesion between the circuit patterns 110 and the first solder resist layer 120.

The first solder resist layer 120 may be formed by coating (applying) the low-viscosity (liquid-type) solder resist ink on the substrate having the circuit patterns 110 formed thereon. As methods for coating (applying) the solder resist ink, there are a screen coating method, a roll coating method, a curtain coating method, and the like. The roll coating method is relatively advantageous in forming the solder resist layer having a uniform thickness as compared to the screen coating method.

The solder resist ink may include a solvent, a photopolymerization initiator, an acryl-based resin, an epoxy-based resin, a filler, and the like. The photopolymerization initiator is modified into a radical by ultraviolet to induce a polymerization reaction of an acrylate-based resin. The epoxy-based resin may be heat-hardened. The filler serves to lower a coefficient of thermal expansion (CTE) of the solder resist ink. These are applied to both of the solder resist layers used in the first and second solder resist layers 120 and 130 described below.

As shown in FIG. 2B, a height difference between the circuit patterns 110 formed on the substrate causes the bending of the first solder resist layer 120. When subsequent processes are performed in the state in which the first solder resist layer is bent, the printed circuit board is also bent. A shape of a fillet becomes non-uniform following an underfill process of the printed circuit board.

A step (S120) of temporally hardening the first solder resist layer includes applying heat to the solder resist layer formed on one surface of the substrate to volatilize the solvent included therein. In this step, the viscosity of the solder resist layer is increased due to volatilization of the solvent, such that a following planarization process may be smoothly performed.

Conditions of the temporal hardening process for facilitating the planarization process may be different according to materials composing the solder resist layer. The conditions of the temporal hardening process for facilitating the planarization process may be different than those of a temporal hardening process for patterning the solder resist layer.

In the present embodiment, as the solder resist ink used in the first solder resist layer, ‘SR-7200g’ available from Hitachi Chemical, Ltd., may be used. The SR-7200g may be temporally hardened at a temperature of 75° C. or more to 80° C. or less for 30 minutes in order to form the solder resist patterns. Meanwhile, the temperature of the primary temporal hardening process prior to the planarization process may be set to the temperature lower than 75° C. or more to 80° C. or less, for example, 40° C. or more to 50° C. or less.

A step (S130) of stacking a second high-viscosity (solid-type) solder resist layer on the first solder resist layer will be described with reference to FIG. 2C. The second solder resist layer 130 is stacked to be in contact with the first solder resist layer using a vacuum laminator.

Since the thickness of the solder resist layer capable of being formed through a single coating may be limited, the second solder resist layer may be additionally formed in order to satisfy the thickness defined in the specification for manufacturing the printed circuit board (the thickness of the second solder resist layer may be controlled through repetitive stacking of the second solder resist layer). In addition, since the thickness of the solder resist layer capable of being efficiently planarized through pressure by a vacuum press, etc., may also be limited, the solder resist layer may be formed through several steps.

In the present embodiment, although the same solder resist ink only having different viscosities may be used in the first solder resist layer 120 and the second solder resist layer 130, the present invention is not limited to the ink having the same component.

In the present embodiment, the second solder resist layer 130 may be made of solder resist ink ‘AUS410,SR1’ available from Tiayo, Ltd.

A step (S140) of planarizing the first solder resist layer by applying pressure to the second solder resist layer will be described with reference to FIG. 2D. When pressure is applied to the second solder resist layer in contact with the first solder resist layer 120, convex portions go down and concave portions are pushed up, such the first solder resist layer 120 is planarized.

In the present embodiment, pressure may be applied to the second solder resist layer using the vacuum press. When the vacuum press is used, a degassing process is performed simultaneously with applying pressure. Therefore, the first and second solder resist layers are more closely adhered to each other.

In the present embodiment, pressure may be applied to a vacuum cover film in a state in which the cover film is attached to the second solder resist layer to be uniformly transferred to the solder resist layer in the planarization process.

As the cover film, a film made of polyester or polyethylene terephthalate (PET) resin may be used. For example, ‘Mylar (registered trade mark of Dupon, Ltd.)’ film may be used. In order to closely adhere the cover film to the second solder resist layer, an adhesive layer may be interposed therebetween. The adhesive layer may include a release agent component. The release agent component may allow the planarization process of the second solder resist layer to be smoothly performed. As the release agent, polydimethysiloxane (PDMS) may be used. The release agent component of the adhesive layer interposed between the cover film and the second solder resist layer facilitates the removal of the cover film.

As described above, the conditions of the temporal hardening process may be changed according to component of the solder resist ink, and may also be changed according to process conditions of a subsequent step (S150) of forming a solder resist pattern.

A step (S150) of forming a solder resist pattern will be described with reference to FIG. 2F. In the case in which the portion of the circuit patterns 110 to be used for connection to elements is covered by the solder resist layers 120 and 130, a patterning process removing the portion is performed.

That is, the portion of the solder resist layers 120 and 130, corresponding to the portion at which the circuit pattern 110 is exposed to the outside is removed. The step of forming the solder resist pattern 140 may be performed through an exposure process and a development process. The exposure process is a process that irradiates light to the solder resist layer, corresponding to a shape of the solder resist pattern 140. In order that light is irradiated to only desired portions, the light may be irradiated in the state in which a mask or an art work film is disposed on the solder resist layer.

As a light source used in the exposure process, a metal halide lamp generating ultraviolet, etc., may be used. In the present embodiment, the light used in the exposure process may be irradiated at the intensity of 360 mJ/cm² in the wavelength of 365 nm, which is an I band.

A photopolymerization initiator in the solder resist ink reacts to the irradiated light to cause polymerization reaction of a resin included in the solder resist ink. As the photopolymerization initiator, there are benzoin alkyl ethers such as benzoin, benzoin methyl ether; anthraquinones such as 2-ethyl anthraquinone or 1-choro anthraquinone; thioxantones such as isopropyl thioxantone or 2,4-diethyl thioxantone; benzophenones such as benzophenone or 4-benzoyl 4′-methyl diphenyl sulfide, and the like. One selected therefrom may be used alone or a mixture of two or more selected therefrom may be used.

The development process is a process that removes portions made of a monomer not polymerized in the solder resist layer after the polymerization reaction occurs by the exposure process. In the present embodiment, the development process may be performed by immersing the printed circuit board subject to the exposure process in 1 wt % of sodium carbonate aqueous solution.

After the solder resist pattern 140 is formed, the circuit pattern 110 to be connected to the element such as a flip chip, etc., is exposed through an opening 150. When the circuit pattern 110 made of copper, etc., is exposed, oxidation phenomenon may occur. Therefore, a finishing process of gold plating the exposed circuit pattern may be additionally performed.

A step (S160) of post-hardening the solder resist pattern will be described with reference to FIG. 2G. After the solder resist pattern 140 is formed, a post-hardening process by heat and light is performed.

The solder resist layer is exposed to an ultraviolet light source, etc., such that photopolymerization reaction in the solder resist pattern 140 may be finished. According to the present embodiment, light may be irradiated at the intensity of 360 mJ/cm² in the exposure process and at the intensity of 1000 mJ/cm² in the post-hardening process.

In addition, heat hardening reaction of the solder resist layer is finished through a heating process. In the present embodiment, the temporal hardening process may be performed at a temperature of 100° C. or less for 60 minutes, and the post-hardening process may be performed at a temperature of 150° C. or less for 60 minutes.

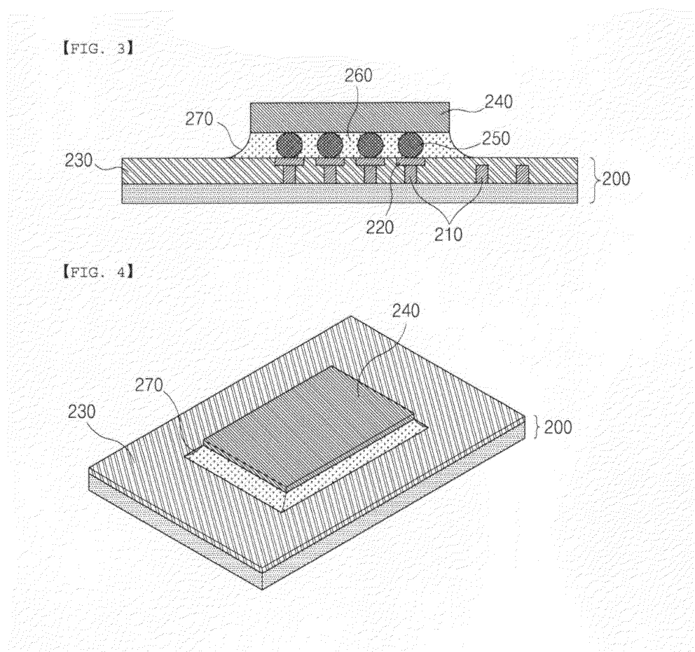

FIG. 3 is a cross-sectional view of a printed circuit board manufactured according to an exemplary embodiment of the present invention and a flip chip bonded to the printed circuit board, and FIG. 4 is a perspective view of a printed circuit board manufactured according to an exemplary embodiment of the present invention and a flip chip bonded to the printed circuit board.

Referring to FIGS. 3 and 4, a printed circuit board 200, circuit patterns 210, bonding pads 220, a solder resist layer 230, a flip chip 240, solder balls 250, an underfill 260, and fillets 270 are shown.

The circuit patterns 210 on the printed circuit board 200 electrically interconnect components bonded to the printed circuit board. Some of the circuit patterns 210 are protected by the solder resist layer. In addition, some of the circuit patterns 210 are connected to electrodes and some of the circuit patterns 210 are connected to the bonding pads 220.

The flip chip 240 is bonded to the printed circuit board 200 using the solder balls 250. The solder balls 250 interposed between the flip chip 240 and the bonding pad 220 provides electrical connection therebetween. A space between the solder balls 250 is formed with the underfill 260 made of an epoxy resin, etc.

The underfill 260 improves reliability according to change in temperature of the flip chip 240, and protects the flip chip 240 from humidity or foreign material. The fillet 270 formed on the outside of the underfill 260 is exposed to the outside. The fillet 270 of the underfill 260 has a uniform shape in the case in which the solder resist layer 230 is flat.

As set forth above, it is possible to provide a printed circuit board including a first low-viscosity solder resist layer and a second high-viscosity solder resist layer stacked on the first solder resist layer, thereby being advantageous in controlling the deviation in application thickness of solder resist (SR), while having excellent adhesion to the PCB, and a manufacturing method thereof.

Although the present invention has been described with reference to exemplary embodiments and the accompanying drawings, it would be appreciated by those skilled in the art that the present invention is not limited thereto but various modifications and alterations might be made without departing from the scope defined in the claims and their equivalents.

1. A printed circuit board, comprising:
a first low-viscosity solder resist layer formed on one surface of a substrate having circuit patterns formed thereon; and
a second high-viscosity solder resist layer stacked on the first solder resist layer.

2. A printed circuit board, comprising:
a first liquid-type solder resist layer formed on one surface of a substrate having circuit patterns formed thereon; and
a second solid-type solder resist layer stacked on the first solder resist layer.

3. The printed circuit board according to claim 1, wherein the first solder resist layer is formed by coating and hardening a solder resist having the viscosity of 1 P or more to 1,000 P or less, and the second solder resist layer is formed by stacking a solder resist having the viscosity of 10,000 P or more to 100,000,000 P or less.

4. The printed circuit board according to claim 1, wherein the second solder resist layer is formed by repetitively stacking at least one solder resist layer.

5. A manufacturing method of a printed circuit board, comprising:
forming a first low-viscosity or liquid-type solder resist layer on one surface of a substrate having circuit patterns formed thereon;
temporally heating the first solder resist layer; and
stacking a second high-viscosity or solid-type solder resist layer on the first solder resist layer.

6. The manufacturing method of a printed circuit board according to claim 5, wherein the forming the first solder resist layer is performed by a roll coating process.

7. The manufacturing method of a printed circuit board according to claim 5, wherein the stacking the second solder resist layer stacks a second high-viscosity or solid-type solder resist as at least one layer.

8. The manufacturing method of a printed circuit board according to claim 5, further comprising planarizing the first solder resist layer by applying pressure to the second solder resist layer, after the stacking the second solder resist layer.

9. The manufacturing method of a printed circuit board according to claim 8, further comprising:
forming a predetermined solder resist pattern in the first and second solder resist layers, corresponding to the circuit patterns; and
hardening the solder resist pattern.

10. The printed circuit board according to claim 2, wherein the first solder resist layer is formed by coating and hardening a solder resist having the viscosity of 1 P or more to 1,000 P or less, and the second solder resist layer is formed by stacking a solder resist having the viscosity of 10,000 P or more to 100,000,000 P or less.

11. The printed circuit board according to claim 2, wherein the second solder resist layer is formed by repetitively stacking at least one solder resist layer.
